(19) United States
(12) Patent Application Publication
(10) Pub. No.: US 2025/0366371 A1
(43) Pub. Date: Nov. 27, 2025

(54) PIEZOELECTRIC DEVICE, APPARATUS, AND POLARIZATION PROCESSING METHOD

(71) Applicant: STANLEY ELECTRIC CO., LTD., Tokyo (JP)

(72) Inventor: Hideo OI, Tokyo (JP)

(73) Assignee: STANLEY ELECTRIC CO., LTD., Tokyo (JP)

(21) Appl. No.: 19/216,489

(22) Filed: May 22, 2025

(30) Foreign Application Priority Data
May 24, 2024 (JP) 2024-085043

(51) Int. Cl. H10N 30/045

(52) U.S. Cl. CPC H10N 30/045

(57) ABSTRACT

The object of the present disclosure is to provide a piezoelectric device and the like capable of suppressing temperature unevenness in a piezoelectric layer during polarization of the piezoelectric device. A piezoelectric device having a capacitor structure in which a first electrode layer having two first electrode terminals, a piezoelectric layer, and a second electrode layer are laminated in this order, wherein the first electrode layer is Joule-heated by a potential difference between the two first electrode terminals, and the piezoelectric layer is polarized by an electric field generated by a potential difference between the first electrode layer and the second electrode layer while being heated by the Joule-heated first electrode layer.

### INCORPORATION BY REFERENCE

This application is based upon and claims the benefit of priority from Japanese patent application No. 2024-085043, filed on May 24, 2024, the disclosure of which is incorporated herein in its entirety by reference.

### BACKGROUND

The present disclosure relates to a piezoelectric device, an apparatus, and a polarization processing method.

There is known a method of performing polarization processing (polling processing) of a piezoelectric layer of a piezoelectric device by applying a heating waveform (electric pulse) and a polling waveform (polling electric field) to the piezoelectric layer of the piezoelectric device having a capacitor structure in which a first electrode layer, a piezoelectric layer (piezoelectric element), and a second electrode layer are laminated in this order (for example, see Patent Literature 1). At this time, the heating waveform is applied to heat the piezoelectric layer of the piezoelectric device. Note that the polarization processing is processing of applying a voltage to a piezoelectric body (piezoelectric element) to align directions of spontaneous polarization.
[Patent Literature 1] Published Japanese Translation of PCT International Publication for Patent Application, No. 2021-512492

### SUMMARY

However, in Published Japanese Translation of PCT International Publication for Patent Application, No. 2021-512492, since the piezoelectric layer of the piezoelectric device is heated by applying a heating waveform to the electrode terminal provided on the first electrode layer and the electrode terminal provided on the second electrode layer, temperature unevenness occurs in the piezoelectric layer of the piezoelectric device due to the arrangement, shape, and the like of each of the electrode terminal provided on the first electrode layer and the electrode terminal provided on the second electrode layer, and as a result, there is a problem that variations occur in characteristics (piezoelectric characteristics) of the piezoelectric layer of the piezoelectric device. In addition, there is also a problem that temperature unevenness occurs in the piezoelectric layer of the piezoelectric device due to film thickness variation of the piezoelectric layer, and as a result, variation occurs in characteristics of the piezoelectric layer of the piezoelectric device.

The present disclosure has been made to solve such a problem, and an object of the present disclosure is to provide a piezoelectric device, an apparatus, and a polarization processing method capable of suppressing temperature unevenness in a piezoelectric layer at the time of polarization of the piezoelectric device.

A piezoelectric device according to the present disclosure is a piezoelectric device having a capacitor structure in which a first electrode layer having two first electrode terminals, a piezoelectric layer, and a second electrode layer are laminated in this order, in which the first electrode layer is Joule-heated by a potential difference between the two first electrode terminals, and the piezoelectric layer is polarized by an electric field generated by a potential difference between the first electrode layer and the second electrode layer while being heated by the first electrode layer Joule-heated.

With such a configuration, it is possible to suppress the occurrence of temperature unevenness in the piezoelectric layer at the time of polarization of the piezoelectric device.

This is because the first electrode layer is Joule-heated due to a potential difference between the two first electrodes, and the piezoelectric layer is heated by the first electrode layer Joule-heated.

In the above piezoelectric device, the two first electrode terminals may be arranged point-symmetrically with respect to the center of the first electrode layer.

In the above piezoelectric device, one of the first electrode layer and the second electrode layer may be an anode electrode layer, and the other may be a cathode electrode layer.

An apparatus according to the present disclosure is an apparatus including the above piezoelectric device.

A polarization processing method according to the present disclosure includes: a first step of applying a heating voltage to two first electrode terminals of a piezoelectric device having a capacitor structure in which a first electrode layer having the two first electrode terminals, a piezoelectric layer, and a second electrode layer are laminated in this order, and generating a potential difference between the two first electrode terminals and between the first electrode layer and the second electrode layer, thereby Joule-heating the first electrode layer and generating a polarization electric field; and a second step of polarizing the piezoelectric layer by the polarization electric field while heating the piezoelectric layer by the first electrode layer Joule-heated.

The above polarization processing method may further include a third step of applying a polarization voltage having a potential difference of 0 V to the two first electrode terminals after a lapse of a predetermined period to generate a potential difference between the first electrode layer and the second electrode layer, thereby stopping Joule-heating of the first electrode layer and generating a polarization electric field.

In the above polarization processing method, in the first step, a rectangular AC voltage as the heating voltage may be applied to one first electrode terminal of the two first electrode terminals, and a rectangular AC voltage having a phase shifted by 180 degrees may be applied as the heating voltage to the other first electrode terminal.

In the above polarization processing method, in the first step, a rectangular AC voltage may be applied as the heating voltage to one first electrode terminal of the two first electrode terminals, and a DC voltage may be applied to the other first electrode terminal.

In the above polarization processing method, a frequency of the rectangular AC voltage may be a frequency in consideration of preventing a current from flowing between the first electrode layer and the second electrode layer.

In the above polarization processing method, the two first electrode terminals may be arranged point-symmetrically with respect to a center of the first electrode layer.

In the above polarization processing method, one of the first electrode layer and the second electrode layer may be an anode electrode layer, and the other may be a cathode electrode layer.

In the above piezoelectric device, the apparatus may be any of a piezoelectric MEMS speaker, a piezoelectric MEMS mirror, and an inkjet printer head.

According to the present disclosure, it is possible to provide a piezoelectric device, an apparatus, and a polarization processing method capable of suppressing temperature unevenness in a piezoelectric layer at the time of polarization of the piezoelectric device.

The above and other objects, features and advantages of the present disclosure will become more fully understood from the detailed 5 description given hereinbelow and the accompanying drawings.

### BRIEF DESCRIPTION OF DRAWINGS

FIG. 1 is a schematic diagram of an apparatus 40 including a piezoelectric device 10;

FIG. 2 is a top view of the piezoelectric device 10;

FIG. 3 is an example of a heating/polarization potential difference generation circuit 20;

FIG. 4A is an example of voltages Va and Vb generated by the heating/polarization potential difference generation circuit 20;

FIG. 4B is another example of voltages Va and Vb generated by the heating/polarization potential difference generation circuit 20;

FIG. 5 is a flowchart of polarization processing (sequence processing) of the piezoelectric device 10;

FIG. 6 is an example of a heating/polarization potential difference generation circuit 20A according to a modified example;

FIG. 7A is an example of voltages Va and Vb generated by a heating/polarization potential difference generation circuit 20A according to the modified example;

FIG. 7B is another example of voltages Va and Vb generated by the heating/polarization potential difference generation circuit 20A of the modified example;

FIG. 8 is an example of a piezoelectric device 10A according to a modified example;

FIG. 9 is a cross-sectional view taken along line IX-IX of FIG. 2;

FIG. 10 is a configuration example of an apparatus 60 (re-polling station) different from the apparatus 40; and

FIG. 11 is a schematic view of a wafer W before singulation on which (a plurality of) piezoelectric devices 10 are formed and a probe 70 for performing polarization processing (see FIG. 5) on each piezoelectric device 10 before singulation.

### DESCRIPTION OF EMBODIMENTS

Hereinafter, a piezoelectric device 10 according to an embodiment of the present disclosure will be described with reference to the accompanying drawings. In the drawings, corresponding components are denoted by the same reference numerals, and repeated descriptions are omitted.

### <Piezoelectric Device 10>

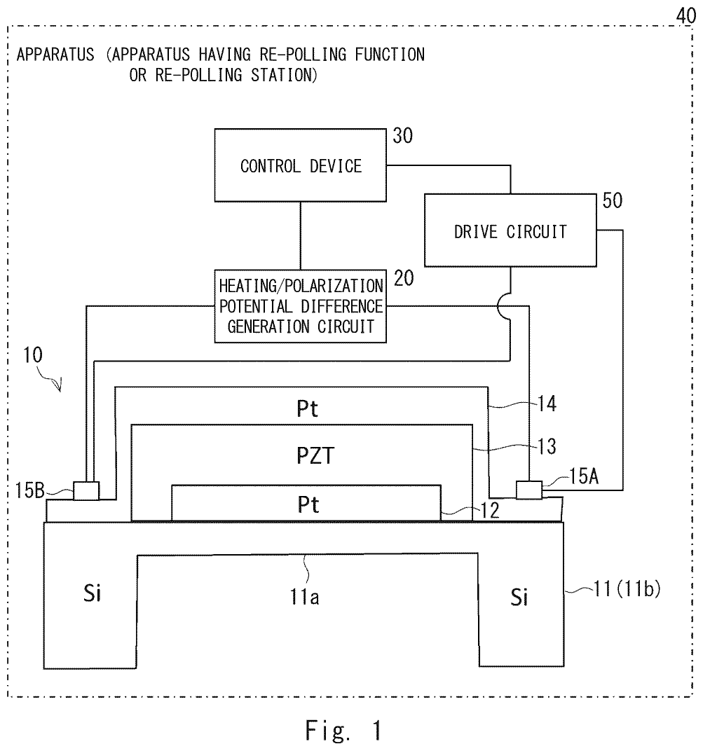

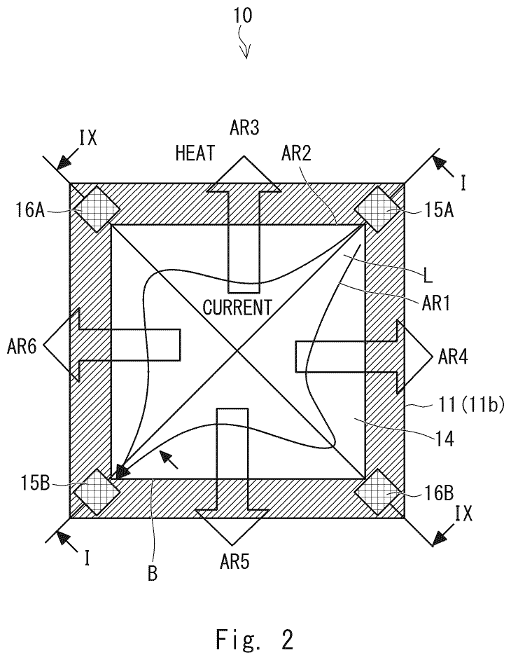

First, the piezoelectric device 10 will be described. FIG. 1 is a schematic view of an apparatus 40 provided with the piezoelectric device 10. The piezoelectric device 10 in FIG. 1 is a cross-sectional view taken along line I-I in FIG. 2. FIG. 2 is a top view of the piezoelectric device 10.

As illustrated in FIGS. 1 and 2, the piezoelectric device 10 is a piezoelectric device having a capacitor structure in which a base material 11, a cathode electrode layer 12, a piezoelectric body 13, and an anode electrode layer 14 are laminated in this order. Hereinafter, an example in which the piezoelectric device of the present disclosure is applied to the piezoelectric device 10 for a piezoelectric MEMS speaker will be described. As illustrated in FIG. 1, the piezoelectric device 10 may be incorporated in the apparatus 40 together with a heating/polarization potential difference generation circuit 20, a control device 30, and a drive circuit 50. The apparatus 40 may be, for example, a piezoelectric MEMS speaker, a piezoelectric MEMS mirror, or an inkjet printer head. The apparatus 40 in which the piezoelectric device 10, the heating/polarization potential difference generation circuit 20, the control device 30, and the drive circuit 50 are incorporated can be referred to as an apparatus having a re-polling function (or an apparatus having a re-polling station).

The base material 11 is made of, for example, Si (silicon substrate), and includes a base material body 11a and a wall 11b provided along an edge of one surface (lower surface) of the base material body 11a.

The cathode electrode layer 12 is, for example, an electrode layer made of Pt (an example of the second electrode layer of the present disclosure), and is laminated on the other surface (upper surface) of the base material body 11a.

The piezoelectric body 13 is, for example, a piezoelectric layer (piezoelectric element) made of PZT, and is laminated on the cathode electrode layer 12.

The anode electrode layer 14 is, for example, an electrode layer made of Pt (an example of the first electrode layer of the present disclosure), and is laminated on the piezoelectric body 13. External shapes of the base material 11, the cathode electrode layer 12, the piezoelectric body 13, and the anode electrode layer 14 are rectangular shapes having substantially the same size in top view.

The anode electrode layer 14 is provided with two first electrode terminals 15A and 15B (see FIG. 1). The two first electrode terminals 15A and 15B are electrically connected to the anode electrode layer 14 by ohmic junction.

In the case of performing polarization processing to be described later, a heating voltage, a polarization voltage, and the like to be described later are applied to the two first electrode terminals 15A and 15B. On the other hand, in a case where the piezoelectric device 10 is caused to function as an actuator or the like of the apparatus 40, a predetermined drive voltage is applied to at least one of the two first electrode terminals 15A and 15B.

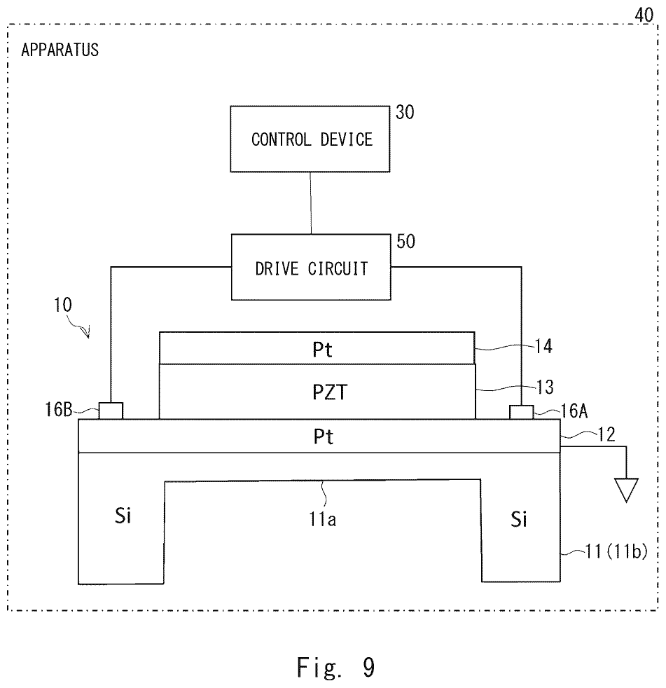

The cathode electrode layer 12 is provided with two second electrode terminals 16A and 16B (see FIG. 9). FIG. 9 is a cross-sectional view taken along line IX-IX of FIG. 2. The two second electrode terminals 16A and 16B are electrically connected to the cathode electrode layer 12 by ohmic junction. Although the cathode electrode layer 12 is connected to GND, it may be connected to GND via the second electrode terminals 16A and 16B. In the embodiment, the second electrode terminals 16A and 16B are connected to GND of the drive circuit 50, but may be connected to GND of the heating/polarization potential difference generation circuit 20.

The drive circuit 50 is electrically connected to the two first electrode terminals 15A and 15B (see FIG. 1) and the two second electrode terminals 16A and 16B (see FIG. 9). The drive circuit 50 drives the piezoelectric body 13 by applying drive voltages of the same potential to the two first electrode terminals 15A and 15B (at least one) under the control of the control device 30 (for example, driven as an actuator). The drive circuit 50 may drive the piezoelectric body 13 by applying a drive voltage between the two first electrode terminals 15A and 15B (at least one) and the two second electrode terminals 16A and 16B (at least one) (for example, it may be driven as an actuator).

The two first electrode terminals 15A and 15B are, for example, electrodes made of Pt and arranged point-symmetrically with respect to the center of the anode electrode layer 14 in top view (see FIG. 2). This has the following advantages. That is, by applying a heating voltage to the two first electrode terminals 15A and 15B and generating a potential difference between the two first electrode terminals 15A and 15B, a current path (see arrows AR1, AR2 in FIG. 2) from one first electrode terminal 15A to the other first electrode terminal 15B is formed in the anode electrode layer 14. This current path is symmetric with respect to a diagonal line L on the way from the one first electrode terminal 15A to the other first electrode terminal 15B, and uniformly (substantially uniformly) spreads over the entire region (substantially the entire region) of the anode electrode layer 14.

Therefore, by applying a heating voltage to the two first electrode terminals 15A and 15B to generate a potential difference between the two first electrode terminals 15A and 15B, the entire region (substantially the entire region) of the anode electrode layer 14 can be Joule-heated. As a result, the piezoelectric body 13 (at least the vibration part) can be uniformly (substantially uniformly) heated by the anode electrode layer 14 Joule-heated.

At this time, the central portion of the anode electrode layer 14 has higher thermal resistance than the outer peripheral portion of the anode electrode layer 14. This is because the wall 11b of the base material 11 having low thermal resistance is provided at a position corresponding to the outer peripheral portion of the anode electrode layer 14. Therefore, the heat of the outer peripheral portion of the anode electrode layer 14 is mainly transferred to the wall 11b of the base material 11 having low thermal resistance (see arrows AR3 to AR6 in FIG. 2). As a result, the central portion of the anode electrode layer 14 has a higher temperature than the outer peripheral portion of the anode electrode layer 14, and the piezoelectric body 13 (at least the vibration part) can be efficiently heated by the anode electrode layer 14 (central portion) having the higher temperature. Note that the vibration part is a portion of the base material body 11a of the piezoelectric body 13 inside the wall 11b of the piezoelectric body 13 in top view (a rectangular inner portion indicated by reference sign B in FIG. 2).

By applying a heating voltage to the two first electrode terminals 15A and 15B to generate a potential difference between the anode electrode layer 14 and the cathode electrode layer 12, a polarization electric field can be generated between the anode electrode layer 14 and the cathode electrode layer 12.

### <Heating/Polarization Potential Difference Generation Circuit 20>

Next, the heating/polarization potential difference generation circuit 20 will be described.

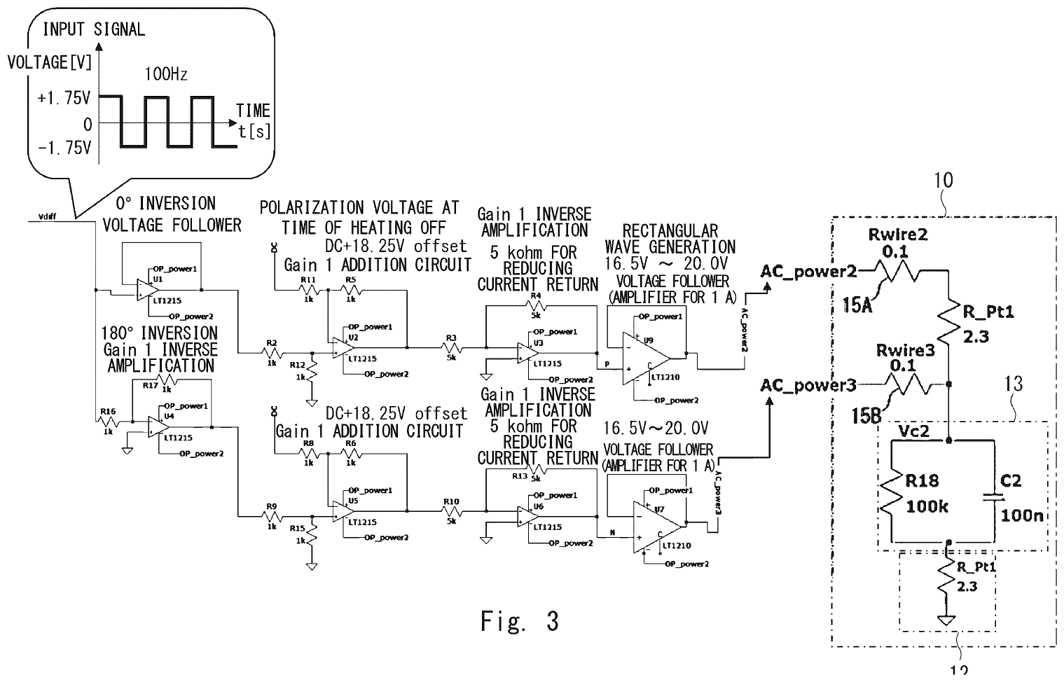

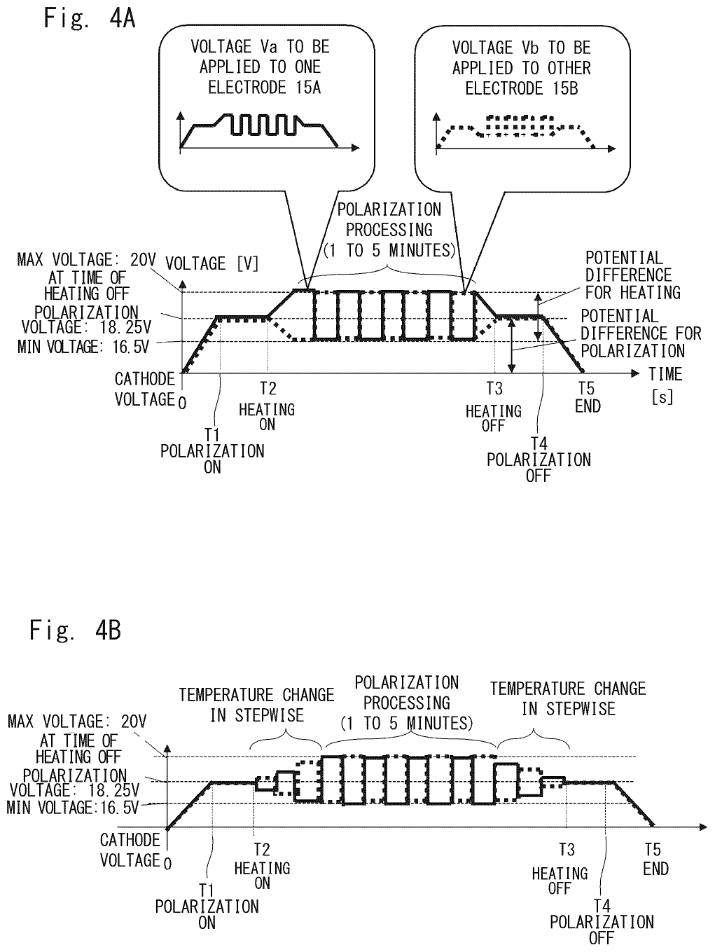

FIG. 3 is an example of the heating/polarization potential difference generation circuit 20. FIG. 4A is an example of the voltages Va and Vb generated by the heating/polarization potential difference generation circuit 20, and FIG. 4B is another example of the voltages Va and Vb generated by the heating/polarization potential difference generation circuit 20. Note that the heating/polarization potential difference generation circuit 20 may be provided in the piezoelectric device 10 (the base material 11 which is a silicon substrate) or may be provided separately from the piezoelectric device 10. The same applies to the control device 30 and the drive circuit 50.

Under the control of the control device 30, the heating/polarization potential difference generation circuit 20 receives an input (input signal) of Pulse±1.75 V (DC 0 V offset) @ 100 Hz, and outputs (generates) a voltage (AC voltage) applied to the two first electrode terminals 15A and 15B, specifically, a voltage Va applied to one first electrode terminal 15A and a voltage Vb applied to the other first electrode terminal 15B.

As illustrated in FIG. 4A, the voltages Va and Vb output from the heating/polarization potential difference generation circuit 20 include, as heating voltages, a rectangular AC voltage applied to one first electrode terminal 15A and a rectangular AC voltage applied to the other first electrode terminal 15B whose phases are shifted by 180 degrees (see voltage Va and voltage VB between time T2 and time T3 in FIG. 4A). The rectangular AC voltage (heating voltage) is applied to the two first electrode terminals 15A and 15B, and a MAX voltage and a MIN voltage are alternately repeated between the two first electrode terminals 15A and 15B to generate a potential difference, so that the anode electrode layer 14 can be Joule-heated. Since the potentials of the two first electrode terminals 15A and 15B also serve as potentials for polarization, an AC voltage is applied between the two first electrode terminals 15A and 15B at the time of heating for the purpose of reducing polarization unevenness due to a potential difference during heating.

Further, the voltages Va and Vb output from the heating/polarization potential difference generation circuit 20 include a voltage having a potential difference of 0 V applied to the two first electrode terminals 15A and 15B as a polarization voltage (see the voltage Va and the voltage VB between time T1 and time T2 and between time T3 and time T4 in FIG. 4A). By applying a voltage (polarization voltage) having a potential difference of 0 V to the two first electrode terminals 15A and 15B to generate a potential difference between the anode electrode layer 14 and the cathode electrode layer 12, a polarization electric field can be generated between the anode electrode layer 14 and the cathode electrode layer 12.

As illustrated in FIG. 4B, the voltages Va and Vb output from the heating/polarization potential difference generation circuit 20 may be voltages that increase and decrease stepwise between time T2 and time T3.

The frequencies of the voltages Va and Vb (heating voltages) output from the heating/polarization potential difference generation circuit 20 are frequencies in consideration of preventing a current from flowing between the anode electrode layer 14 and the cathode electrode layer 12 (so as not to cause insufficient output). Specifically, the frequencies of the voltages Va and Vb (heating voltages) output from the heating/polarization potential difference generation circuit 20 are desirably low frequencies (approximately less than 200 Hz) based on the capacitance of the piezoelectric body 13.

### <Example of Polarization Processing of Piezoelectric Device 10>

Next, an example of polarization processing of the piezoelectric device 10 having the above configuration will be described. The following processing is mainly realized by the heating/polarization potential difference generation circuit 20.

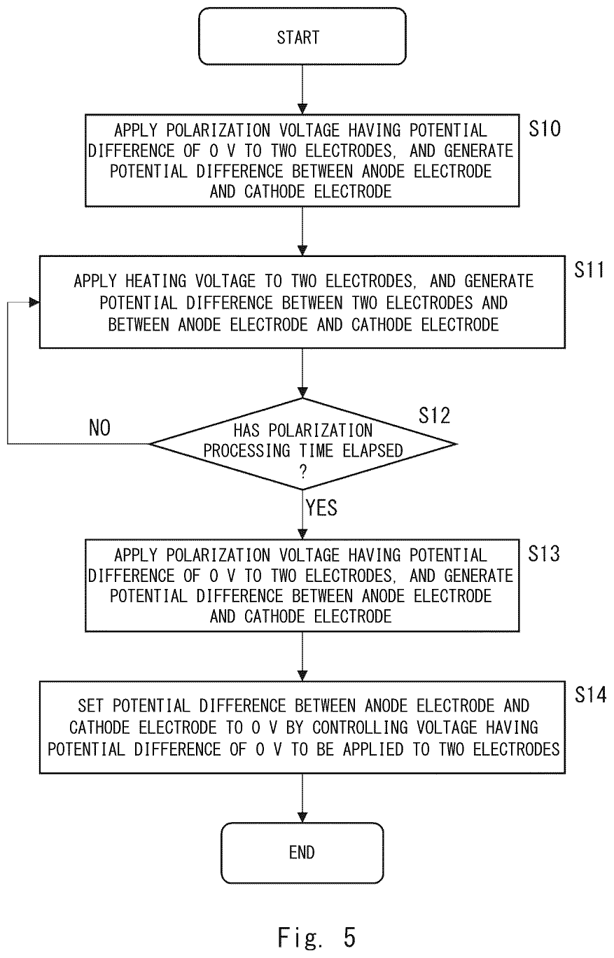

FIG. 5 is a flowchart of polarization processing (sequence processing) of the piezoelectric device 10.

First, a polarization voltage having a potential difference of 0 V (polarization voltage at the time of heating OFF) is applied to the two first electrode terminals 15A and 15B to generate a potential difference between the anode electrode layer 14 and the cathode electrode layer 12 (step S10). Specifically, as illustrated in FIG. 4A, between time T1 and time T2, 18.25 V (see the thick solid line in FIG. 4A) is applied to one first electrode terminal 15A, and 18.25 V (see the thick dotted line in FIG. 4A) is applied to the other first electrode terminal 15B. As a result, a polarization electric field (polarization electric field at the time of heating OFF) is generated between the anode electrode layer 14 and the cathode electrode layer 12. Between time T1 and time T2, the potential difference between the two first electrode terminals 15A and 15B is 0 V, and the potential difference between the anode electrode layer 14 and the cathode electrode layer 12 is 18.25 V. Since the potential difference between the two first electrode terminals 15A and 15B is 0 V between time T1 and time T2, the anode electrode layer 14 is not Joule-heated (heating is stopped).

Next, a heating voltage is applied to the two first electrode terminals 15A and 15B to generate potential differences between the two first electrode terminals 15A and 15B and between the anode electrode layer 14 and the cathode electrode layer 12 (step S11). Specifically, as illustrated in FIG. 4, rectangular AC voltages Va and Vb (MAX voltage 20 V, MIN voltage 16.5 V) are applied as heating voltages to the two first electrode terminals 15A and 15B between time T2 and time T3.

By generating a potential difference between the two first electrode terminals 15A and 15B, the anode electrode layer 14 can be Joule-heated. By generating a potential difference between the anode electrode layer 14 and the cathode electrode layer 12, a polarization electric field can be generated between the anode electrode layer 14 and the cathode electrode layer 12.

As a result, the piezoelectric body 13 (at least the vibration part) can be polarized by the polarization electric field while the piezoelectric body 13 (at least the vibration part) is Joule-heated by the anode electrode layer 14. That is, the heating and polarization processing of the piezoelectric body 13 (at least the vibration part) can be simultaneously performed. At this time, since the two first electrode terminals 15A and 15B are arranged point-symmetrically with respect to the center of the anode electrode layer 14 in top view (see FIG. 2), the entire region (substantially the entire region) of the anode electrode layer 14 can be Joule-heated. As a result, the piezoelectric body 13 (at least the vibration part) can be uniformly (substantially uniformly) heated by the anode electrode layer 14 Joule-heated.

The processing in step S11 is repeatedly executed until the polarization processing time (for example, 1 to 5 minutes) elapses (step S12: NO).

On the other hand, in a case where the polarization processing time (for example, 1 to 5 minutes) has elapsed (step S12: YES), that is, a polarization voltage having a potential difference of 0 V (voltage for polarization at the time of heating OFF) is applied to the two first electrode terminals 15A and 15B to generate a potential difference between the anode electrode layer 14 and the cathode electrode layer 12 (step S13). This is similar to the processing in step S10.

Specifically, as illustrated in FIG. 4A, between time T3 and time T4, 18.25 V (see the thick solid line in FIG. 4A) is applied to one first electrode terminal 15A, and 18.25 V (see the thick dotted line in FIG. 4A) is applied to the other first electrode terminal 15B. As a result, a polarization electric field (polarization electric field at the time of heating OFF) is generated between the anode electrode layer 14 and the cathode electrode layer 12. Between time T3 and time T4, the potential difference between the two first electrode terminals 15A and 15B is 0 V, and the potential difference between the anode electrode layer 14 and the cathode electrode layer 12 is 18.25 V. Since the potential difference between the two first electrode terminals 15A and 15B is 0 V between time T3 and time T4, the anode electrode layer 14 is not Joule-heated (heating is stopped).

Next, the potential difference between the anode electrode layer 14 and the cathode electrode layer 12 is set to 0 V by controlling the voltage of the potential difference 0 V applied to the two first electrode terminals 15A and 15B (step S14).

Thus, the polarization processing of the piezoelectric device 10 is completed.

As described above, according to the present embodiment, it is possible to suppress the occurrence of temperature unevenness in the piezoelectric body 13 (piezoelectric layer) at the time of polarization of the piezoelectric device 10.

This is because the anode electrode layer 14 (first electrode layer) is Joule-heated due to a potential difference between the two first electrode terminals 15A and 15B, and the piezoelectric body 13 is Joule-heated by the anode electrode layer 14.

In addition, according to the present embodiment, since the potential difference between the two first electrode terminals 15A and 15B is independent for heating and the potential difference between the anode electrode layer 14 and the cathode electrode layer 12 is independent for polarization, it is possible to control heating ON/OFF while applying a polarization electric field and to control the polarization electric field ON/OFF before and after heating by sequence processing (see FIG. 5).

In addition, according to the present embodiment, since the polarization processing can be performed while the temperature is controlled by the device alone without using an external heating mechanism, the number of chips to be processed is not limited by depolarization which is a problem in the manufacturing process.

Further, according to the present embodiment, since the external heating mechanism is not used, it is possible to perform polarization processing for ensuring characteristics even after product shipment.

In addition, according to the present embodiment, a low frequency that does not cause a current to flow in the piezoelectric body 13 can be used for the current path by the anode electrode layer 14 alone, and it is possible to suppress the calorific value and polarization unevenness due to the current variation in the capacitor, which are conventional problems.

According to the present embodiment, the owner (for example, an individual who has purchased the apparatus 40) of the apparatus 40 (apparatus having a re-polling function or polling station) in which the piezoelectric device 10, the heating/polarization potential difference generation circuit 20, the control device 30, and the drive circuit 50 are incorporated can perform polarization processing (local heating/polarization) without preparing a special heating furnace. That is, the owner of the apparatus 40 can individually perform the polarization processing when an abnormality occurs in the operation of the piezoelectric device 10 built in the apparatus 40 owned by the owner (or periodically). Therefore, the direction of the spontaneous polarization of the piezoelectric device 10 built in the apparatus 40 owned by the owner can be aligned, the risk of the depolarization of the piezoelectric body 13 due to the temporal change can be individually solved, and the piezoelectric effect can be restored to the factory shipment level.

Next, a modified example will be described.

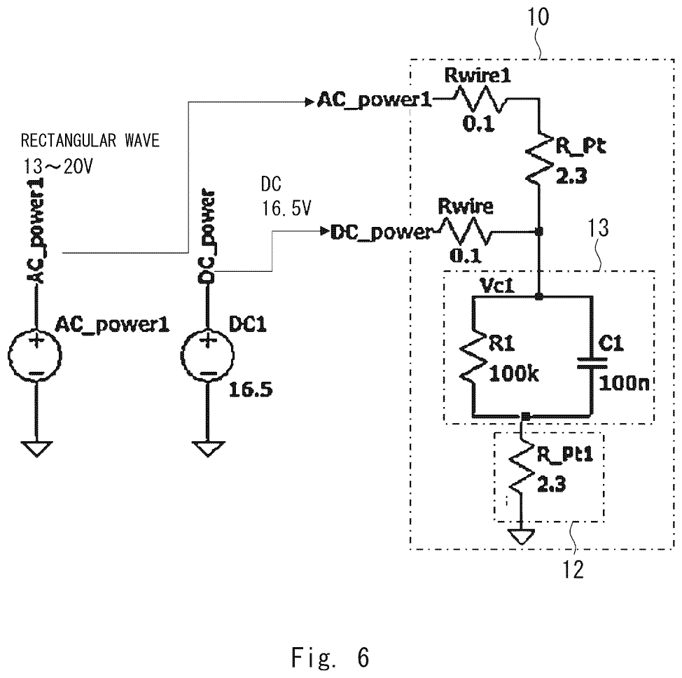

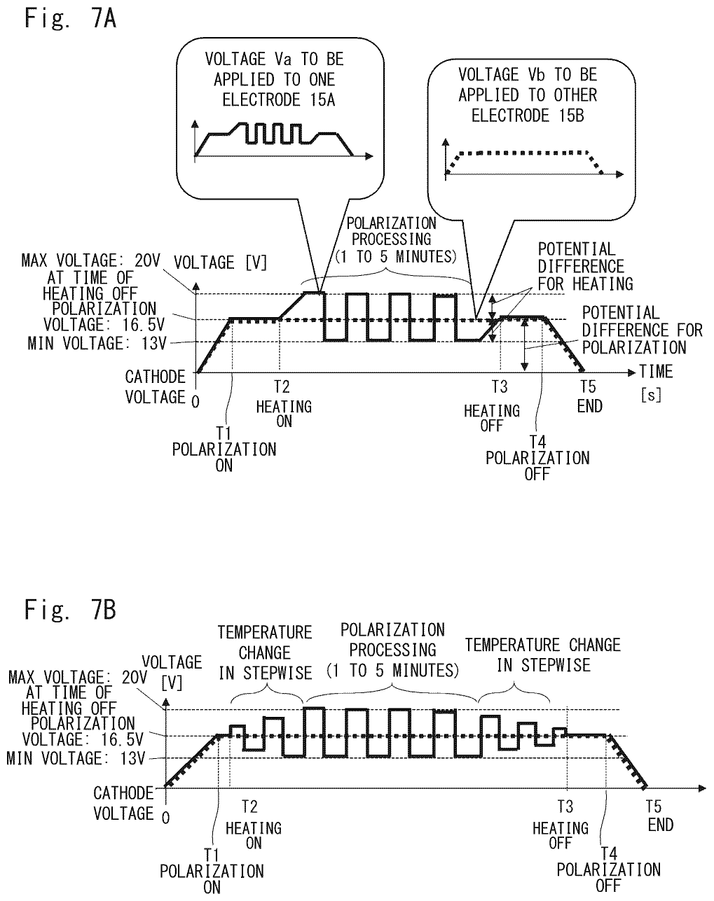

FIG. 6 is an example of a heating/polarization potential difference generation circuit 20A according to a modified example. FIG. 7A is an example of the voltage Va generated by the heating/polarization potential difference generation circuit 20A of the modified example, and FIG. 7B is another example of the voltage Va generated by the heating/polarization potential difference generation circuit 20A of the modified example.

As illustrated in FIG. 7A, the heating/polarization potential difference generation circuit 20A according to the modified example outputs (generates) an alternating current (AC) voltage (rectangular wave (13 to 20 V)) applied to one first electrode terminal 15A and a direct current (DC) voltage 16.5 V applied to the other first electrode terminal 15B according to control from the control device 30.

As illustrated in FIG. 7B, the voltage Va output from the heating/polarization potential difference generation circuit 20A may be a voltage that increases or decreases stepwise between time T2 and time T3.

According to the present modified example, the configuration of the heating/polarization potential difference generation circuit 20A can be simplified as compared with the heating/polarization potential difference generation circuit 20 illustrated in FIG. 3.

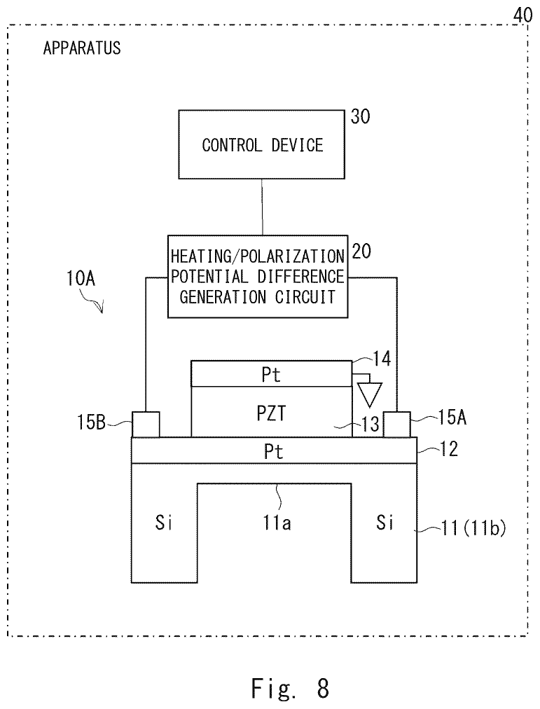

FIG. 8 is an example of a piezoelectric device 10A according to a modified example.

In the above embodiment, an example in which the two first electrode terminals 15A and 15B are provided in the anode electrode layer 14 has been described, but the present invention is not limited thereto. For example, as illustrated in FIG. 8, two first electrode terminals 15A and 15B may be provided in the cathode electrode layer 12.

According to the present modified example, the same effects as those of the above embodiment can be obtained.

In the above embodiment, an example in which the piezoelectric device of the present disclosure is applied to the piezoelectric device 10 for a piezoelectric MEMS speaker has been described, but the present invention is not limited thereto. For example, the piezoelectric device of the present disclosure may be applied to any type of piezoelectric device other than the piezoelectric device 10 for a piezoelectric MEMS speaker, for example, a piezoelectric MEMS mirror, a piezoelectric device for an inkjet printer head. At that time, the piezoelectric device 10, the heating/polarization potential difference generation circuit 20, and the control device 30 may be configured as a re-polling station of the piezoelectric device. The present invention is not limited thereto, and the piezoelectric device 10, the heating/polarization potential difference generation circuit 20, and the control device 30 may be configured as a polling apparatus (polarization apparatus) of a piezoelectric device (piezoelectric MEMS device) at a wafer level. In this way, since heating and polarization can be locally performed without depolarization of adjacent chips, it is possible to expect shortening of cooling time since heating is locally performed.

In the above embodiment, an example in which the heating/polarization potential difference generation circuit 20 and the control device 30 are incorporated in the apparatus 40 has been described, but the present invention is not limited thereto.

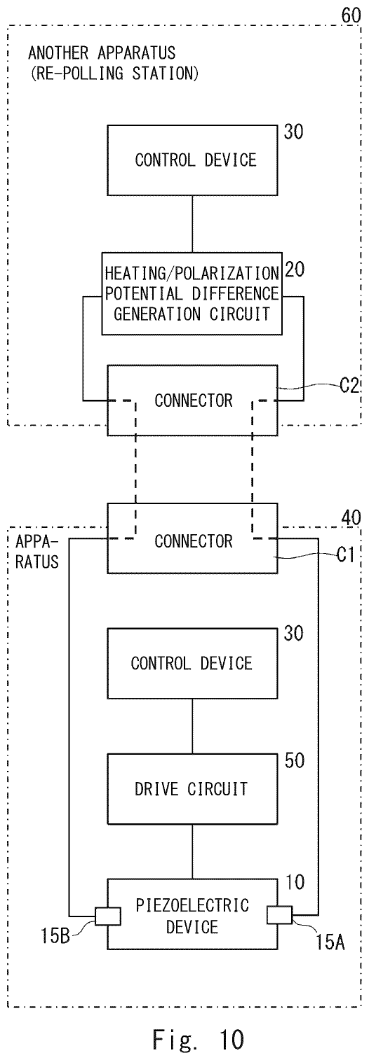

For example, as illustrated in FIG. 10, the heating/polarization potential difference generation circuit 20 and the control device 30 may be provided in an apparatus 60 (re-polling station) different from the apparatus 40. FIG. 10 illustrates a configuration example of an apparatus 60 (re-polling station) different from the apparatus 40.

As illustrated in FIG. 10, another apparatus 60 (re-polling station) includes a connector C2 electrically connected to the heating/polarization potential difference generation circuit 20 in addition to the heating/polarization potential difference generation circuit 20 and the control device 30. On the other hand, the apparatus 40 includes a connector C1 electrically connected to the two first electrode terminals 15A and 15B in addition to the piezoelectric device 10, the control device 30, and the drive circuit 50.

According to the present modified example, by connecting (physically and electrically connecting) the connector C1 and the connector C2, the two first electrode terminals 15A and 15B and the heating/polarization potential difference generation circuit 20 can be electrically connected as in FIGS. 1 and 9. Thus, polarization processing (see FIG. 5) can be performed on the piezoelectric device 10 in the apparatus 40. At that time, although not illustrated, the second electrode terminals 16A and 16B (at least one) are electrically connected to GND of the apparatus 60.

According to the present modified example, the same effects as those of the above embodiment can be obtained.

Further, according to the present modified example, a shop that sells the piezoelectric device 10, a manufacturer of a shipping source, or the like can provide the owner with an after-sales service for restoring the piezoelectric effect of the piezoelectric device 10 to a factory shipment level.

In the above embodiment, the example in which the polarization processing (see FIG. 5) is performed on the piezoelectric device 10 built in the apparatus 40 has been described, but the present invention is not limited thereto.

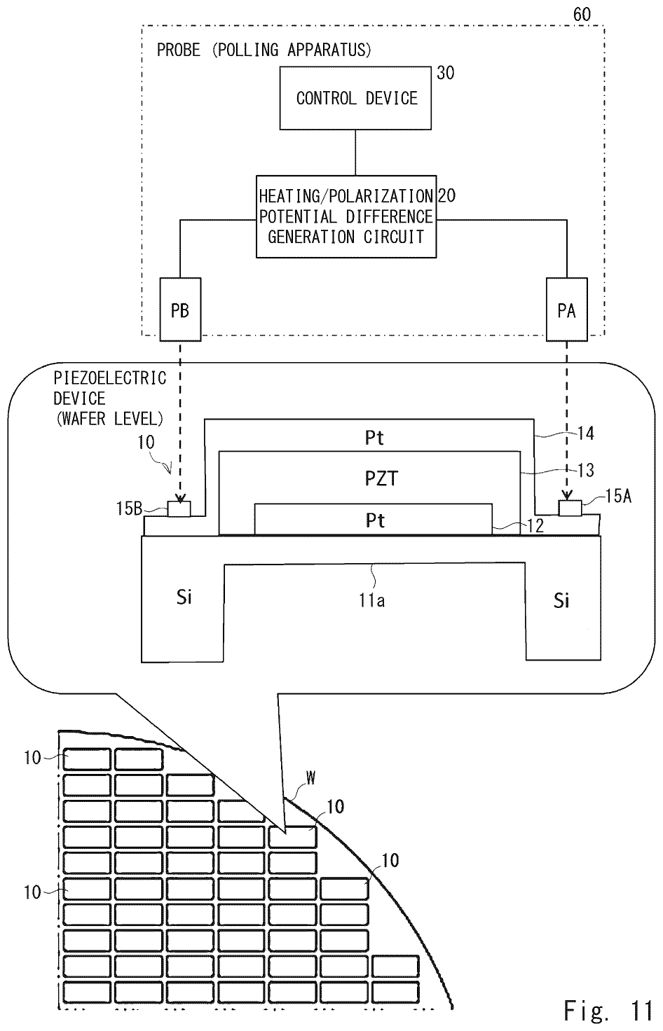

For example, polarization processing (see FIG. 5) may be performed on the piezoelectric device 10 before being incorporated in the apparatus 40. For example, as illustrated in FIG. 11, polarization processing (see FIG. 5) may be performed on each piezoelectric device 10 in the stage of the wafer (for example, a Si wafer) before singulation (chipping). FIG. 11 is a schematic view of a wafer W before singulation on which (a plurality of) piezoelectric devices 10 are formed and a probe 70 for performing polarization processing (see FIG. 5) on each piezoelectric device 10 before singulation. The piezoelectric devices 10 are electrically insulated from each other.

As illustrated in FIG. 11, the probe 70 (polling apparatus) includes the heating/polarization potential difference generation circuit 20, the control device 30, and contacts PA and PB (for example, probe needles) electrically connected to the heating/polarization potential difference generation circuit 20.

According to the present modified example, by moving the probe 70 using a predetermined moving mechanism (not illustrated) and electrically connecting the contacts PA and PB and the two first electrode terminals 15A and 15B of the piezoelectric device 10 before singulation, the two first electrode terminals 15A and 15B and the heating/polarization potential difference generation circuit 20 can be electrically connected as in FIGS. 1 and 9. As a result, polarization processing (see FIG. 5) can be performed on the piezoelectric device 10 before singulation.

For example, in a case where a set of contacts PA and PB is provided, the probe 70 is moved using a predetermined moving mechanism (not illustrated) to electrically connect (a set of) the contacts PA and PB and (a set of) the two first electrode terminals 15A and 15B of one piezoelectric device 10 before singulation, whereby the polarization processing (see FIG. 5) can be performed on one piezoelectric device 10 before singulation.

In addition, for example, in a case where a plurality of sets of contacts PA and PB are provided, the probe 70 is moved using a predetermined moving mechanism (not illustrated), and (a plurality of sets of) the contacts PA and PB and (a plurality of sets of) the two first electrode terminals 15A and 15B of the plurality of piezoelectric devices 10 before singulation are electrically connected, whereby the polarization processing (see FIG. 5) can be simultaneously performed on the plurality of piezoelectric devices 10 before singulation. At that time, although not illustrated, the second electrode terminals 16A and 16B (at least one) are electrically connected to GND of the apparatus 60.

According to the present modified example, the same effects as those of the above embodiment can be obtained. In addition, according to the present modified example, it can be used for local heating and polarization processing before factory shipment, and polarization processing can be performed at low cost without equipment such as a heating furnace.

In the above embodiment, an example of the apparatus 40 as a piezoelectric MEMS speaker in which the piezoelectric device 10, the heating/polarization potential difference generation circuit 20, and the control device 30 are built has been described, but the present invention is not limited thereto. For example, the apparatus 40 in which the piezoelectric device 10, the heating/polarization potential difference generation circuit 20, and the control device 30 are incorporated may be any type of apparatus other than the piezoelectric MEMS speaker, for example, an inkjet printer.

Each numerical value illustrated in the above embodiments is an example, and it is a matter of course that an appropriate numerical value different from this can be used.

The above embodiments are merely examples in all respects. The present disclosure is not to be construed as being limited by the description of the above embodiments. The present disclosure can be implemented in various other forms without departing from the spirit or main characteristics thereof.

What is claimed is:

1. A piezoelectric device having a capacitor structure in which a first electrode layer having two first electrode terminals, a piezoelectric layer, and a second electrode layer are laminated in this order, wherein
the first electrode layer is Joule-heated by a potential difference between the two first electrode terminals, and
the piezoelectric layer is polarized by an electric field generated by a potential difference between the first electrode layer and the second electrode layer while being heated by the first electrode layer Joule-heated.

2. The piezoelectric device according to claim 1, wherein the two first electrode terminals are arranged point-symmetrically with respect to a center of the first electrode layer.

3. The piezoelectric device according to claim 1, wherein
one of the first electrode layer and the second electrode layer is an anode electrode layer, and
the other is a cathode electrode layer.

4. An apparatus comprising a piezoelectric device according to claim 1.

5. A polarization processing method comprising:
a first step of applying a heating voltage to two first electrode terminals of a piezoelectric device having a capacitor structure in which a first electrode layer having the two first electrode terminals, a piezoelectric layer, and a second electrode layer are laminated in this order, and generating a potential difference between the two first electrode terminals and between the first electrode layer and the second electrode layer, thereby Joule-heating the first electrode layer and generating a polarization electric field; and
a second step of polarizing the piezoelectric layer by the polarization electric field while heating the piezoelectric layer by the first electrode layer Joule-heated.

6. The polarization processing method according to claim 5, further comprising a third step of applying a polarization voltage having a potential difference of 0 V to the two first electrode terminals after a lapse of a predetermined period to generate a potential difference between the first electrode layer and the second electrode layer, thereby stopping Joule-heating of the first electrode layer and generating a polarization electric field.

7. The polarization processing method according to claim 5, wherein
in the first step, a rectangular AC voltage as the heating voltage is applied to one first electrode terminal of the two first electrode terminals, and
a rectangular AC voltage having a phase shifted by 180 degrees is applied as the heating voltage to the other first electrode terminal.

8. The polarization processing method according to claim 5, wherein
in the first step, a rectangular AC voltage is applied as the heating voltage to one first electrode terminal of the two first electrode terminals, and
a DC voltage is applied to the other first electrode terminal.

9. The polarization processing method according to claim 7, wherein a frequency of the rectangular AC voltage is a frequency in consideration of preventing a current from flowing between the first electrode layer and the second electrode layer.

10. The polarization processing method according to claim 5, wherein the two first electrode terminals are arranged point-symmetrically with respect to a center of the first electrode layer.

11. The polarization processing method according to claim 5, wherein one of the first electrode layer and the second electrode layer is an anode electrode layer, and the other is a cathode electrode layer.

12. The apparatus according to claim 4, wherein the apparatus is any of a piezoelectric MEMS speaker, a piezoelectric MEMS mirror, and an inkjet printer head.
